(19) United States
(12) Patent Application Publication
(10) Pub. No.: US 2007/0249142 A1
(43) Pub. Date: Oct. 25, 2007

(54) Semiconductor devices and method of manufacturing them

(75) Inventor: Yukihiro Hisanaga, Toyota-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Toyota Jidosha Kabushiki Kaisha

(21) Appl. No.: 11/785,456

(22) Filed: Apr. 18, 2007

(30) Foreign Application Priority Data
Apr. 19, 2006 (JP) 2006-115316

(51) Int. Cl. H01L 29/08; H01L 21/30

(52) U.S. Cl. 438/459; 257/30

(57) ABSTRACT

In a conventional semiconductor device, an insulator film is formed between a p-type semiconductor region and an n-type semiconductor region of a super junction structure, thereby preventing the mutual diffusion of impurities between the two regions. The manufacturing processes used to produce semiconductor devices with this configuration were complex.

A semiconductor device of the present invention comprises a super junction structure in which a pair semiconductor regions, comprising of a p-type semiconductor region and an n-type semiconductor region, is disposed repeatedly along at least one direction, wherein a Si_{1-x-y}GeₓC_{y} (0≦x<1, 0<y<1, 0<-x-y<1) crystal region is disposed repeatedly along, at least, the aforementioned direction, and a Si crystal region forming either one of the p-type semiconductor region and the n-type semiconductor region is disposed between a pair of the Si_{1-x-y}GeₓC_{y} crystal regions.

### CROSS-REFERENCE TO RELATED APPLICATIONS

The present application claims priority based on Japanese Patent Application 2006-115316 filed on Apr. 19, 2006, the contents of which are hereby incorporated by reference within this application.

### BACKGROUND OF THE INVENTION

1. Field of the Invention

The present invention relates to a method of preventing the mutual diffusion of impurities between a p-type semiconductor region and an n-type semiconductor region that form a super junction structure.

Semiconductor devices that have a super junction structure formed by repeating a p-type semiconductor region and an n-type semiconductor region are already known. In this type of semiconductor device, mutual diffusion of the impurity in the p-type semiconductor region and the impurity in the n-type semiconductor region, that form the super junction structure, may occur. This diffusion may cause a deterioration of the characteristics of the semiconductor device.

To counteract this, as shown in FIG. 18, an insulator film (SiO₂) 128 is formed between a p-type semiconductor region 124 and an n-type semiconductor region 122 in a semiconductor device of Patent Document 1. The diffusion of impurities between the p-type semiconductor region 124 and the n-type semiconductor 122 is thus prevented. In order to realize this structure, a plurality of trenches 123 is formed in an n-type Si crystal substrate. The trenches 123 extend from a top surface of the n-type Si crystal substrate towards the bottom, and are formed repeatedly with a predetermined distance between adjacent trenches. The insulator film 128 is formed across the entire surface of the inner walls of the trenches 123, and then the insulator film 128 formed on a bottom part of the trenches 123 is removed. Next, as shown by the boldface arrows, Si crystal that contains the p-type impurity is grown by the epitaxial method from the bottom part of the trenches 123. A super junction structure 126 is thus formed. This type of semiconductor device is described in, for example, Japanese Laid-open Patent Publication No. 2003-374951.

In the instance where a film for preventing the diffusion of impurities is an insulator film (SiO₂), it is known that it is difficult to cause epitaxial growth of Si crystal from the insulator film due to this insulator film having an amorphous state. It is consequently necessary to perform a process for causing the epitaxial growth of the Si crystal within the trench that has been surrounded by the insulator film. For example, in the aforementioned prior art, a process for removing the insulator film 128 from the bottom part of the trenches 123 is performed, and then the Si crystal is grown, using the epitaxial method, from the bottom part of the trenches 123 that have had the insulator film 128 removed therefrom. The process of removing the insulator film 128 from the bottom part of the trenches 123 was necessary in the prior art.

The present invention was invented to solve the aforementioned problem.

The present invention discloses a semiconductor device and a method of manufacturing the semiconductor device wherein it is possible to prevent the mutual diffusion of impurities between a p-type semiconductor region and an n-type semiconductor region that form a super junction structure, and wherein the manufacturing process can be simplified.

### SUMMARY OF THE INVENTION

The semiconductor device according to the invention comprises a super junction structure in which pairs of semiconductor regions, containing a p-type semiconductor region and an n-type semiconductor region, are disposed repeatedly along at least one direction. In this super junction structure, a Si_{1-x-y}GeₓC_{y} (0≦x<1, 0<y<1, 0<1-x-y<1) crystal region is disposed repeatedly along, at least, the aforementioned direction, and a Si crystal region is disposed between the pairs of Si_{1-x-y}GeₓC_{y} crystal regions.

The Si_{1-x-y}GeₓC_{y} crystal may be formed independently by crystal growth. Furthermore, the Si_{1-x-y}GeₓC_{y} crystal may be formed by vapor phase diffusion of Ge and C into Si crystal. Furthermore, the Si_{1-x-y}GeₓC_{y} crystal may be formed by implanting Ge and C into Si crystal.

Furthermore, the Si_{1-x-y}GeₓC_{y} crystal may be any type out of p-type, n-type, or non-dope type (i-type).

The diffusion length of impurity in the Si_{1-x-y}GeₓC_{y} crystal (0≦x<1, 0<y<1, 0<1-x-y<1) is approximately three orders of magnitude smaller than that of impurity in the Si crystal. As a result, if a super junction structure is formed by repeating the joining structures of the Si crystal and the S_{1-x-y}GeₓC_{y} crystal, it is possible to prevent the mutual diffusion of impurities between the p-type semiconductor regions and the n-type semiconductor regions that form the super junction structure. For example, both the p-type semiconductor regions and the n-type semiconductor regions may be formed from Si crystal, and Si_{1-x-y}GeₓC_{y} crystal film may be interposed between the two. In this instance, the Si_{1-x-y}GeₓC_{y} crystal film functions as a diffusion preventing film. Alternatively, either the p-type semiconductor regions or the n-type semiconductor regions may be formed from Si crystal and the other regions formed from Si_{1-x-y}GeₓC_{y} crystal. In this instance, the speed of diffusion in the region formed from the Si_{1-x-y}GeₓC_{y} crystal is slower, and consequently it is possible to prevent the mutual diffusion of impurities between the p-type semiconductor regions and the n-type semiconductor regions.

In addition, the Si_{1-x-y}GeₓC_{y} crystal may be formed by crystal growth from the Si crystal. Alternatively, the Si crystal may be formed by crystal growth from the Si_{1-x-y}GeₓC_{y} crystal. The manufacturing process of the semiconductor device can thus be simplified.

In the semiconductor device according to this invention, the Si_{1-x-y}GeₓC_{y} crystal region may be disposed between the p-type Si crystal region forming the p-type semiconductor region and the n-type Si crystal region forming the n-type semiconductor region.

In this instance, the film of Si_{1-x-y}GeₓC_{y} crystal separates the p-type semiconductor regions and the n-type semiconductor regions that form the super junction structure. Since the speed of diffusion is slow in the Si_{1-x-y}GeₓC_{y} crystal interposed between the p-type semiconductor regions and the n-type semiconductor regions, it is possible to prevent the mutual diffusion of the p-type impurity and the n-type impurity. Furthermore, the process of manufacturing the semiconductor device can be simplified because the process of removing the Si_{1-x-y}GeₓC_{y} crystal is not required.

In the semiconductor device according to this invention, the numerical value of ‘y’ for the Si_{1-x-y}GeₓC_{y} crystal region may vary along the aforementioned direction.

It is possible to adjust the speed of diffusion of the impurities by varying the numerical value of ‘y’ for the Si_{l-x-y}GeₓC_{y} crystal. Furthermore, it is possible to adjust the lattice constant by varying the numerical value of ‘x’. When a plurality of films are formed with differing ‘x’ and ‘y’ values, it is possible to prevent the diffusion of impurities between the p-type Si crystal and the n-type Si crystal by providing films in which the diffusion length of impurity is slow. In addition, it is possible to control the occurrence of misfit dislocation caused by mismatch of the lattice constant by reducing the difference between the lattice constants at a junction between the Si crystal and the S_{1-x-y}GeₓC_{y} crystal.

In the semiconductor device according to this invention, the numerical value of ‘x’ and the numerical value of ‘y’ for the Si_{1-x-y}GeₓC_{y} crystal region may decrease from one side of the Si_{1-x-y}GeₓC_{y} crystal region toward the other side thereof, the one side of the Si_{1-x-y}GeₓC_{y} crystal region facing one Si crystal region at one side, and the other side of the Si_{1-x-y}GeₓC_{y} crystal region facing another Si crystal region at the other side.

In this instance, it is possible to increase the elemental ratio of Si the closer the film is to a surface adjoining the other Si crystal. It is thus possible to control lattice mismatch at the junction adjoining the other Si crystal. It is simultaneously possible to increase the elemental ratio of C the closer the film is to a surface adjoining the one Si crystal. It is thus possible to effectively prevent the mutual diffusion of impurities between the one Si crystal and the other Si crystal by means of a film that contains C. Furthermore, if necessary, it is possible to control lattice mismatch at the junction by also increasing the elemental ratio of Ge at the side where the elemental ratio of C is greater.

In the semiconductor device according to this invention, either the p-type semiconductor region or the n-type semiconductor region may be made of the Si crystal, and the other may be made of the Si_{1-x-y}GeₓC_{y} crystal.

Using this structure, as well, it is possible to realize a super junction structure.

In this instance, the process of manufacturing the super junction structure can be simplified.

In the semiconductor device according to this invention, the numerical value of ‘y’ for the Si_{1-x-y}GeₓC_{y} (0≦x<1, 0<y<1, 0<1-x-y<1) crystal may be greater than or equal to 0.5×10⁻².

When the elemental ratio of C in the Si_{1-x-y}GeₓC_{y} crystal is greater than or equal to 0.5 percent, the diffusion length of impurity in the Si_{1-x-y}GeₓC_{y} is slowed markedly. When a super junction structure is formed utilizing Si_{1-x-y}GeₓC_{y} crystal wherein the elemental ratio of C is greater than or equal to 0.5 percent, it is possible to effectively prevent the diffusion of impurities between the p-type semiconductor region and the n-type semiconductor region. Moreover, this is applicable not only in the instance where the p-type Si crystal and the n-type Si crystal are separated by the Si_{1-x-y}GeₓC_{y} crystal, but also in the instance where either the p-type semiconductor region or the n-type semiconductor region is formed from Si crystal, and the other is formed from Si_{1-x-y}GeₓC_{y} crystal.

In a method of manufacturing a semiconductor device of the invention, wherein the semiconductor device includes a super junction structure in which pairs of semiconductor regions, comprising of a p-type semiconductor region and an n-type semiconductor region, are disposed repeatedly along at least one direction, the method comprises forming a plurality of trenches, each of the trenches extending from a top surface of a semiconductor substrate made of Si crystal towards a bottom surface of the semiconductor substrate, and being disposed repeatedly with a predetermined distance between adjacent trenches. The method further comprises forming Si_{1-x-y}GeₓC_{y} crystal (0≦x<1, 0<y<1, 0<1-x-y<1) within the trenches.

In the process of forming the Si_{1-x-y}GeₓC_{y} crystal within the trenches, the Si_{1-x-y}GeₓC_{y} crystal may be grown from the wall surfaces of the trenches. Furthermore, in this process, the Si_{1-x-y}GeₓC_{y} crystal may be formed by vapor phase diffusion of Ge and C into the Si crystal surrounding the trenches. In addition, in this process, the Si_{1-x-y}GeₓC_{y} crystal may be formed by implanting Ge and C into the Si crystal.

Additionally, in this process, after the film of Si_{1-x-y}GeₓC_{y} crystal has been formed in the trenches, the remaining spaces in the trenches may be filled with Si crystal, or may be filled with Si_{1-x-y}GeₓC_{y} crystal.

Furthermore, the Si_{1-x-y}GeₓC_{y} crystal (0≦x<1, 0<y<1, 0<1-x-y<1) may be any type of the following types: p-type, n-type, or non-dope type (i-type).

In this manufacturing method, Si_{1-x-y}GeₓC_{y} crystal (here, 0≦x<1, 0<y<1, 0<1-x-y<1) is formed within the trenches. The diffusion length of impurity in the Si_{1-x-y}GeₓC_{y} crystal is approximately three orders of magnitude smaller than that of impurity in the Si crystal. As a result, if the Si_{1-x-y}GeₓC_{y} crystal is formed between the Si crystals along the repeating direction of the super junction structure, it is possible to prevent the mutual diffusion, between the Si crystals, of the impurities contained in the Si crystals.

Furthermore, the Si_{1-x-y}GeₓC_{y} crystal can be grown from the Si crystal by crystal growth, and the Si crystal can also be grown from the Si_{1-x-y}GeₓC_{y} crystal by crystal growth. It is not necessary to remove the impurity diffusion preventing film from the bottom part of the trenches as is necessary in the conventional art. The manufacturing process of the semiconductor device can thus be simplified.

The method of manufacturing defined by the present invention may comprise growing Si crystal on a surface of the Si_{1-x-y}GeₓC_{y} crystal coating an inner surface of the trenches.

This method is applied so as to realize a structure wherein p-type Si crystal and n-type Si crystal are separated by a Si_{1-x-y}GeₓC_{y} crystal film.

In this manufacturing method, the central part of the trenches is formed from Si crystal. The growth rate of crystal is faster for Si crystal than for Si_{1-x-y}GeₓC_{y} crystal. As a result, it is possible to reduce the time required for filling the trenches with semiconductor crystal. Furthermore, since it is possible to grow the Si crystal from the side walls of the trenches, the time required for filling the trenches with the Si crystal can be made shorter than in the conventional art where crystal was grown only from the bottom part of the trenches.

In the method of manufacturing defined by the present invention, the process of growing the Si_{1-x-y}GeₓC_{y} crystal may be controlled so that the numerical value of ‘y’ for the Si_{1-x-y}GeₓC_{y} crystal varies along at least the aforementioned direction.

It is possible to adjust the speed at which the impurities diffuse by varying the numerical value of ‘y’ for the Si_{1-x-y}GeₓC_{y} crystal. Furthermore, if necessary, it is possible to adjust the lattice constant by varying the numerical value of ‘x’. When a plurality of films are formed with differing ‘x’ and ‘y’ values, it is possible to prevent the diffusion of impurities between the p-type Si crystal and the n-type Si crystal by providing films in which the speed of diffusion is slow. In addition, it is possible to control the occurrence of misfit dislocation caused by mismatch of the lattice constants by reducing the difference between the lattice constants at the junction between the Si crystal and the Si_{1-x-y}GeₓC_{y} crystal.

In the method of manufacturing defined by the present invention, the process of growing the Si_{1-x-y}GeₓC_{y} crystal may be controlled so that an elemental ratio of Si (1-x-y) gradually increases in accordance with the growth of the Si_{1-x-y}GeₓC_{y} crystal. Furthermore, the process of the growing the Si crystal may be continued even after the elemental ratio of Si reaches ‘1.0’, at least until the trenches are filled.

Accordingly, it is possible during a continuing process of growing the crystals to form a single Si crystal in the central part of the trenches by, for example, increasing the concentration of Si in the vapor utilized for the vapor phase growth while the crystal growth is taking place. The growth rate of crystal is faster for Si crystal than for Si_{1-x-y}GeₓC_{y} crystal (0≦x<1, 0<y<1, 0<1-x-y<1). As a result, it is possible to reduce the time required for filling the trenches with crystal.

In the method of manufacturing defined by the present invention, the process of growing the Si_{1-x-y}GeₓC_{y} crystal may be continued until the trenches are filled with the Si_{1-x-y}GeₓC_{y} crystal.

This method is applied in the instance where either the p-type semiconductor region or the n-type semiconductor region is formed from Si crystal and the other thereof is formed from Si_{1-x-y}GeₓC_{y} crystal.

Accordingly, since the region at one side of the super junction structure is formed only of Si_{1-x-y}GeₓC_{y} crystal (0≦x<1, 0<y<1, 0<1-x-y<1), the process of forming the super junction structure can be simplified.

According to the semiconductor devices of the present invention and the method of manufacturing them, it is possible to prevent the mutual diffusion of impurities between the p-type semiconductor regions and the n-type semiconductor regions that form a super junction structure, and it is possible to simplify the manufacturing process. It is possible to simplify the process of manufacturing an extremely fine super junction structure wherein the p-type semiconductor regions and the n-type semiconductor regions are repeated, where these having an extremely small pitch that is small enough to disturb the super junction structure due to the diffusion distance of the impurities.

### BRIEF DESCRIPTION OF THE DRAWINGS

FIG. 1 schematically shows the configuration of a semiconductor device that is a vertical MOS type FET.

FIG. 2 is a figure showing a manufacturing process of the semiconductor device.

FIG. 3 is a figure showing a manufacturing process of the semiconductor device.

FIG. 4 is a figure showing a manufacturing process of the semiconductor device.

FIG. 5 is a figure showing a manufacturing process of the semiconductor device.

FIG. 6 is a figure showing a manufacturing process of the semiconductor device.

FIG. 7 is a figure showing a manufacturing process of the semiconductor device.

FIG. 8 schematically shows the configuration of a variant of the semiconductor device.

FIG. 9 schematically shows the configuration of a variant of the semiconductor device.

FIG. 10 schematically shows the configuration of a semiconductor device that is a horizontal MOS type FET.

FIG. 11 schematically shows the configuration of a semiconductor device that is configured as a diode.

FIG. 12 is a figure showing the configuration of an impurity diffusion preventing film of the semiconductor device.

FIG. 13 is a figure showing the configuration of an impurity diffusion preventing film of the semiconductor device.

FIG. 14 is a figure showing the configuration of an impurity diffusion preventing film of the semiconductor device.

FIG. 15 is a figure showing the configuration of a semiconductor device wherein the entirety of n-type semiconductor regions 22h is formed from Si_{1-x-y}GeₓC_{y} crystal (0≦x<1, 0<y<1, 0<1-x-y<1).

FIG. 16 is a figure showing the configuration of an impurity diffusion preventing film of the semiconductor device.

FIG. 17 is a figure showing the configuration of an impurity diffusion preventing film of the semiconductor device.

FIG. 18 schematically shows the configuration of a conventional semiconductor device.

### DETAILED DESCRIPTION OF THE INVENTION

### Description of the Preferred Features

The preferred features of the present invention will be described below.

### (First Preferred Feature)

A thickness d of the Si_{1-x-y}GeₓC_{y} crystal (0≦x<1, 0<y<1, 0<1-x-y<1) is set to be thicker than the sum of thicknesses required in manufacturing processes (manufacturing process 1˜manufacturing process N), these thicknesses being: d1>2 (D₁×t₁)^{1/2}, d2>2 (D₂×t₂^{1/2} . . . , dN>2 (D_{N}×t_{N})^{1/2}. Here, Dᵢ is the impurity difflusion coefficient at the ith manufacturing process, and tᵢ is the duration of the ith manufacturing process.

### Description of the Preferred Embodiments

### First Embodiment

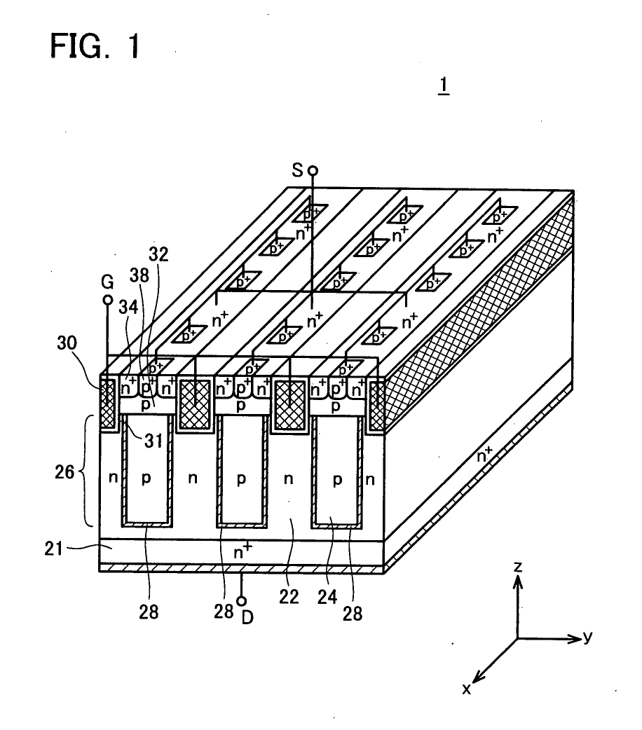

A semiconductor device 1 to which the semiconductor device of the present invention has been applied will be described with reference to FIGS. 1 to 7. The semiconductor device 1 of the first embodiment is configured as a vertical MOS type FET comprising a super junction structure in a drift region. In the semiconductor device 1, an impurity diffusion preventing film formed from Si_{1-x-y}GeₓC_{y} crystal (0≦x<1, 0<y<1, 0<1-x-y<1) is formed at an edge of a p-type semiconductor region of the super junction structure.

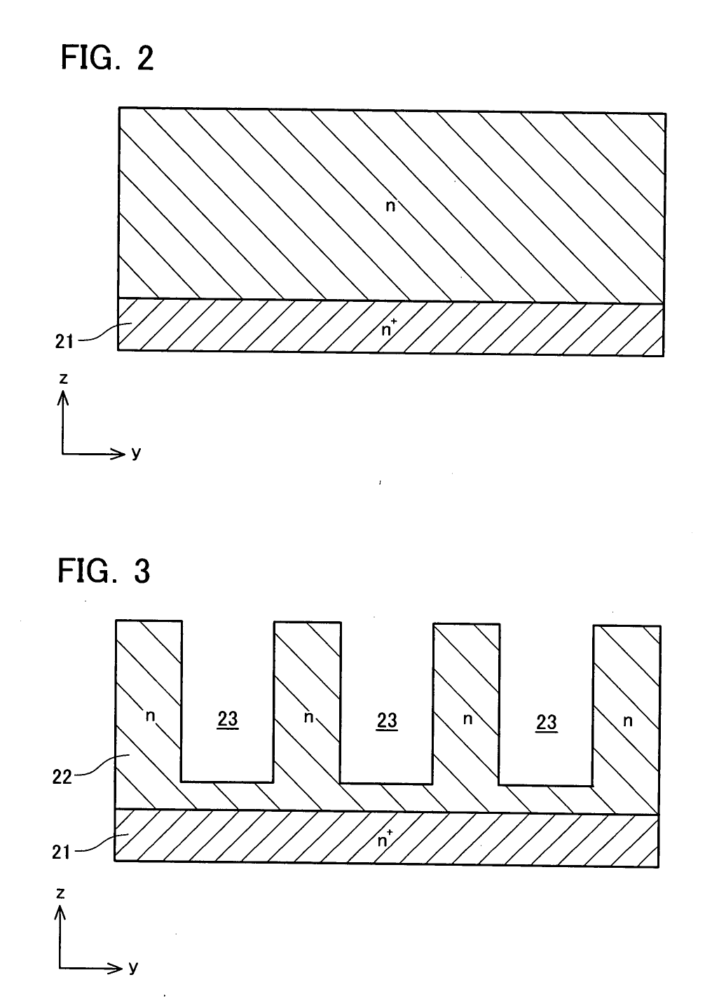

FIG. 1 schematically shows the configuration of the semiconductor device 1. FIGS. 2 to 7 are figures showing manufacturing processes of the semiconductor device 1.

As shown in FIG. 1, a source electrode S and a gate electrode G are provided at a surface side (the top side in FIG. 1) of the semiconductor device 1. The source electrode S and the gate electrode G are insulated by an interlayer insulation film. In addition, a drain electrode D is provided at a bottom side (the lower side in FIG. 1) of the semiconductor device 1.

An n⁺ type drain region 21 is formed on the drain electrode D. A drift region comprising a super junction structure 26 is formed on the drain region 21. A p-type body region 32 is formed on the drift region 21 (sic). An n⁺type source region 34 and a p⁺ type body contact region 38 are formed selectively in the p-type body region 32. The n⁺ type source region 34 and the p⁺ type body contact region 38 are connected with the source electrode S.

Furthermore, the semiconductor device 1 is provided with a trench gate electrode 30 that extends along the direction joining the n⁺ type source electrode S and the drift region (the z direction in FIG. 1). The trench gate electrode 30 is adjacent to the n⁺ type source region 34. Furthermore, the trench gate electrode 30 passes through the p-type body region 32 and reaches an n-type semiconductor region 22 that comprises the super junction structure 26. The trench gate electrode 30 faces the p-type body region 32 via a gate insulator film 31.

In the super junction structure 26, p-type semiconductor regions 24 are formed in the n-type semiconductor regions 22, with these p-type semiconductor regions 24 extending in the z direction to a predetermined depth. The p-type semiconductor regions 24 extend continually in the x direction of the figure, and are repeated at predetermined intervals along the y direction of the figure. The super junction structure 26 is realized thereby. An impurity diffusion preventing film 28 is formed at a junction between the n-type semiconductor regions 22 and the p-type semiconductor regions 24 of the super junction structure 26. The impurity diffusion preventing film 28 is formed using Si_{0.91}Ge_{0.08}C_{0.01}.

Next, the key steps of the method of manufacturing the semiconductor device 1 will be described with reference to FIGS. 2 to 7.

As shown in FIG. 2, an n-type Si epitaxial growth film is grown to a thickness of 100 μm on the drain region 21 that consists of an n⁺ type Si single crystal substrate (thickness 700 μm). Then, as shown in FIG. 3, trenches 23 (depth 50 μm, opening width 1 μm, pitch between trenches 1 μm) are formed by dry etching (anisotropic etching) such as RIE. An n-type semiconductor region 22 having spacing present therein can thus be formed.

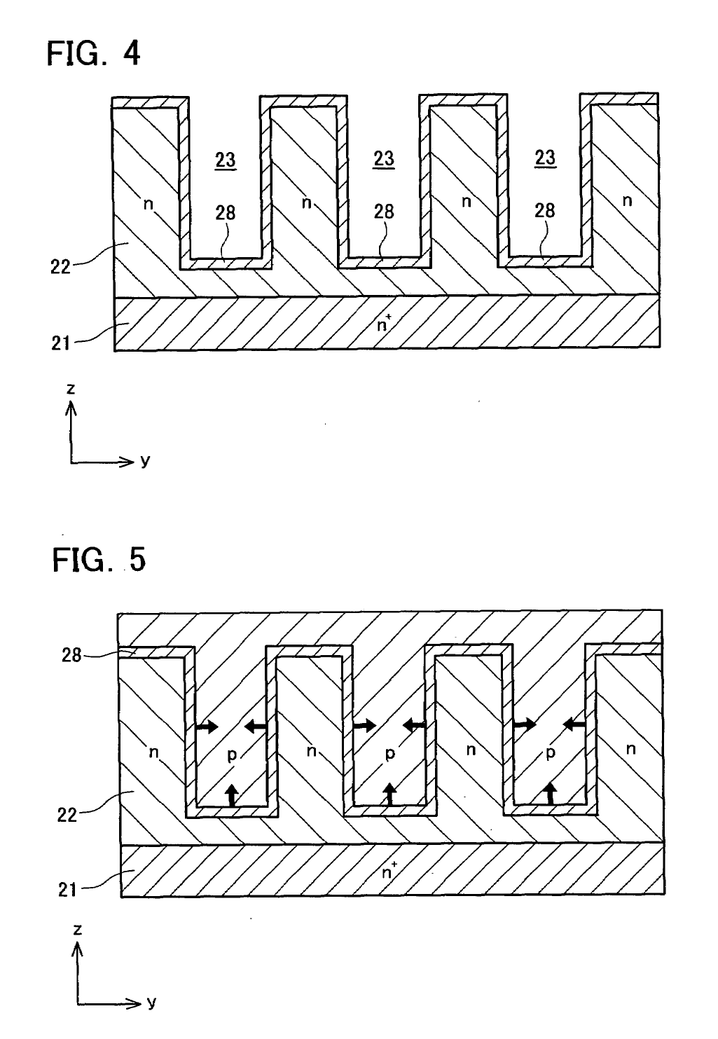

Next, as shown in FIG. 4, the impurity diffusion preventing film 28 is formed by causing the crystal growth of a p-type Si_{0.91}Ge_{0.08}C_{0.01} film (thickness 80 nm) on the surface side. The impurity diffusion preventing film 28 forms a perfect lattice match with the Si epitaxial growth film that forms the n-type semiconductor region 22.

Then, as shown in FIG. 5, a p-type Si film (thickness 800 nm) is grown on the impurity diffusion preventing film 28, completely sealing the interior of the trench 23. At this juncture, crystal growth can be performed, using the impurity diffusion preventing film 28, in the directions shown by the boldface arrows in FIG. 5.

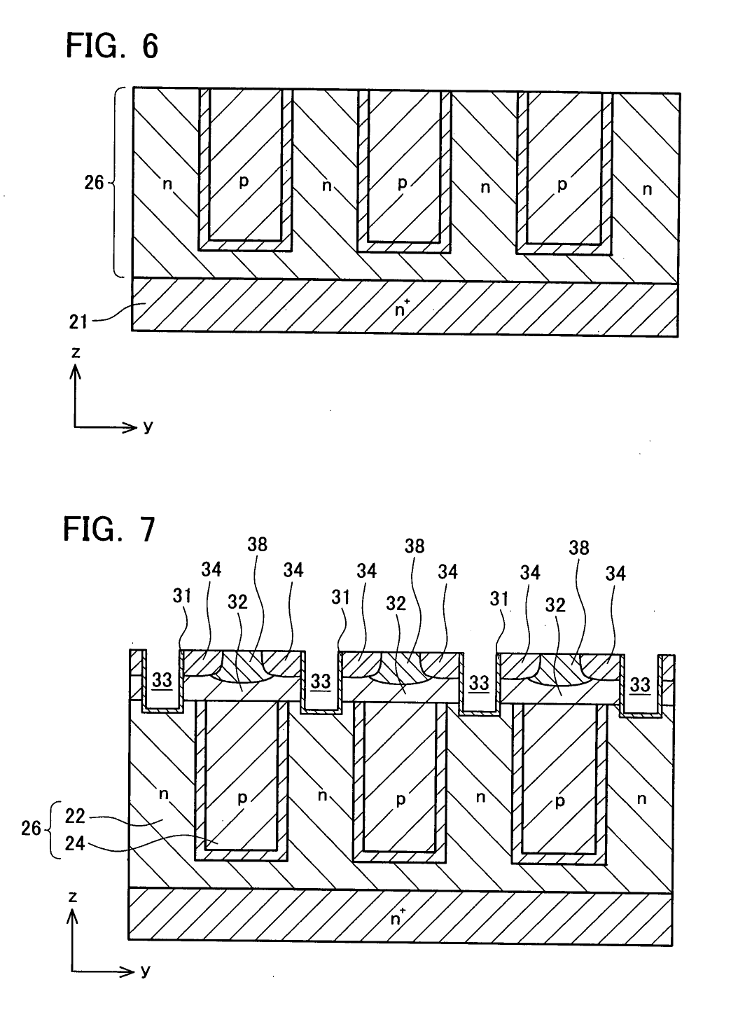

Next, as shown in FIG. 6, the surface Si film and the impurity diffusion preventing film 28 are removed by Chemical Mechanical Polishing (CMP), forming the super junction structure 26.

Then, as shown in FIG. 7, the p-type body region 32 is formed by crystal growth on the super junction structure 26, and then the source region 34 and the body contact region 38 are formed on the surface of the body region 32. Then trenches 33 are formed that pass from the surface of the source region 34, through the body region 32 and into the n-type semiconductor region 22 of the super junction structure 26. Then a mask (not shown) is applied at the surface side, and the gate oxide film 31 (SiO₂) is formed on inner walls of the trenches 33. Furthermore, electrode material is filled into the trenches 33, forming the trench gate electrodes 30. The disposal of the source region 34, the body contact region 38, and the trench gate electrodes 30 at the surface side has a known configuration, and these regions are manufactured according to known methods. Consequently, a detailed description thereof is omitted.

In FIGS. 2 to 7, the configurational elements are displayed with dimensions that have been reduced from the actual dimensions (for example, the drain region 21 is displayed as thinner, the trenches 23 are displayed as deeper, and the impurity diffusion preventing films 28 are displayed as thicker) in order to render the figures easier to comprehend.

Here, although the impurity diffusion preventing film 28 of the semiconductor device 1 of the present embodiment has been formed from Si_{0.91}Ge_{0.08}C_{0.01} film, the elemental ratio thereof is not limited to this embodiment. When the composition of this alloy film is represented as Si_{1-x-y}GeₓC_{y}, the elemental ratio of silicon (Si), germanium (Ge), and carbon (C) may vary providing the conditions 0≦x<1, 0<y<1, and 0<1-x-y<1 are satisfied. As a result, the alloy film may be a SiC film (a film where x=0). Although the thickness of the impurity diffusion preventing film 28 may be up to 10 nm, it is preferred that the composition of the alloy film includes germanium (Ge) in the instances where the thickness of the impurity diffusion preventing film 28 is 10 nm or above. The reason for the aforementioned preference is described below.

It is possible to effectively prevent the mutual diffusion of the p-type impurity from the p-type semiconductor regions 24 and the n-type impurity from the n-type semiconductor regions 22 by having the composition of the impurity diffusion preventing film 28 include carbon (C). However, carbon (C) has a smaller crystal lattice constant than silicon (Si), and consequently the crystal lattice constant of the impurity diffusion preventing film 28 that consists of a SiGeC alloy film is reduced. The greater the difference in the crystal lattice constants between the impurity diffusion preventing film 28 and the n-type silicon (Si) film joining therewith, the easier it is for misfit dislocations to occur as a result of lattice mismatch between the impurity diffusion preventing film 28 and the n-type silicon (Si) film. To deal with this, germanium (Ge) is included in the composition of the impurity diffusion preventing film 28. Germanium (Ge) has a larger crystal lattice constant than silicon (Si), and consequently the crystal lattice constant of the impurity diffusion preventing film 28 that consists of a SiGeC alloy film is increased. If the elemental ratio of the Si, Ge, and C is thus adjusted, then, an alloy film which has a crystal lattice constant that differs only slightly from the crystal lattice constant of the n-type silicon (Si) film adjoining the impurity diffusion preventing film 28 can be utilized for the film 28. An impurity diffusion preventing film 28 can be formed in which mismatch of the lattice constant with the n-type silicon (Si) film does not readily occur.

With respect to the numerical values of ‘x’ and ‘y’ in Si_{1-x-y}GeₓC_{y}, it is known that generally a crystal that satisfies the relationship x=8.22y (Si_{9.22y}Ge_{8.22y}C_{y}) forms a perfect lattice match with Si crystal film within the range 0≦y≦0.108. At the same time if the elemental ratio of the carbon (C) is greater than or equal to 0.005, an adequate diffusion preventing effect with respect to the impurities can be achieved. As a result, if the impurity diffusion preventing film 28 is formed from an alloy film having a composition satisfying the above conditions, misfit dislocation does not readily occur even if the thickness of the impurity diffusion preventing film 28 is 10 nm or above. So, in the present embodiment, an example is described wherein y=0.01 and x=0.08.

Since the mutual diffusion of impurities between the p-type semiconductor region and the n-type semiconductor region tends to be sped up by heating the semiconductor film during the manufacturing process, the thickness of the impurity diffusion preventing film 28 is set so as to suit the heat history of the manufacturing processes. For example, in a case where the heat history in a manufacturing process (here this will be termed a first manufacturing process) has a temperature of 1000 degrees Celsius and a time of t (seconds), and the impurity diffusion coefficient is D (cm²/seconds), the thickness d1 (nm) of the impurity diffusion preventing film 28 required for this heat history may be any thickness satisfying the conditions ‘d1>2 (D×t)^{1/2}’. Here, if D=1.2×10⁻¹⁷ (cm²/seconds), and t=3600 (seconds), then ‘d1>2 (nm)’. By adjusting the elemental ratio of the carbon (C) with respect to the boron (B) or phosphorous (P) that is usually used as the impurity, D=1.2×10⁻¹⁷ (cm²/seconds) can be realized comparatively easily.

The thickness d1 (nm)˜dN (nm) of the impurity diffusion preventing film 28 required in each of the first˜Nth manufacturing processes (heating processes) is thus calculated, the sum thereof is found, and the thickness d of the impurity diffusion preventing film 28 is set so as to be thicker than this sum (i.e. 2(D₁×t₁)^{1/2}+2(D₂×t₂)^{1/2} . . . (D_{N}×t_{N})^{1/2}=d1+d2+ . . . d_{N}<d). Here, Dᵢ is the impurity diffusion coefficient at the ith manufacturing process, and tᵢ is the duration of the ith manufacturing process.

In the semiconductor device 1 of the present embodiment, an impurity diffusion preventing film 28 that contains Si_{0.91}Ge_{0.08}C_{0.01} crystal having a thickness of 80 nm is formed on inner walls of the trenches 23 formed in the p-type semiconductor regions 24. When the elemental ratio of carbon (C) in the Si_{0.91}Ge_{0.08}C_{0.01} crystal is greater than or equal to 0.005, the diffusion length of impurity is approximately three orders of magnitude smaller than that of impurity in Si crystal. As a result, if this type of crystal is formed in the repeating direction of the super junction structure 26 between the p-type semiconductor regions 24 and the n-type semiconductor regions 22, it is possible to prevent the mutual diffusion of the p-type impurity and the n-type impurity contained in the Si crystals between the p-type semiconductor regions 24 and the n-type semiconductor regions 22.

Furthermore, the Si_{0.91}Ge_{0.08}C_{0.01} crystal may be any type out of p-type, n-type, or non-dope type (i-type). The carriers of the semiconductor device 1 flow across the n-type semiconductor regions 22, there is no increase in resistance even when the Si_{0.91}Ge_{0.08}C_{0.01} is i type.

Furthermore, when the p-type semiconductor regions 24 adjoining the Si_{0.91}Ge_{0.08}C_{0.01} crystal are to be formed, the Si crystal of the p-type semiconductor regions 24 can be grown from the Si_{0.91}Ge_{0.08}C_{0.01} crystal. Furthermore, since the Si crystal and the Si_{0.91}Ge_{0.08}C_{0.01} crystal satisfy the relationship wherein the numerical values of ‘x’ and ‘y’ in Si_{1-x-y}GeₓC_{y} are generally x=8.22y and 0≦y≦0.108, misfit dislocation does not readily occur. Thus, it is not necessary to remove the film formed at the bottom part of the trenches as in the conventional art. The manufacturing process of the semiconductor device can thus be simplified.

Moreover, the central part of the p-type semiconductor regions 24 is formed from Si crystal. The growth rate of crystal is faster for Si crystal than for Si_{0.91}Ge_{0.08}C_{0.01} crystal. As a result, it is possible to reduce the time required for filling the trenches 23 with semiconductor crystal. Furthermore, since it is possible to grow the Si crystal from the side walls of the trenches 23 as well, the time required for filling the trenches 23 with the Si crystal is less than in the conventional art where crystal growth occurs only from the bottom part of the trenches

### Second Embodiment

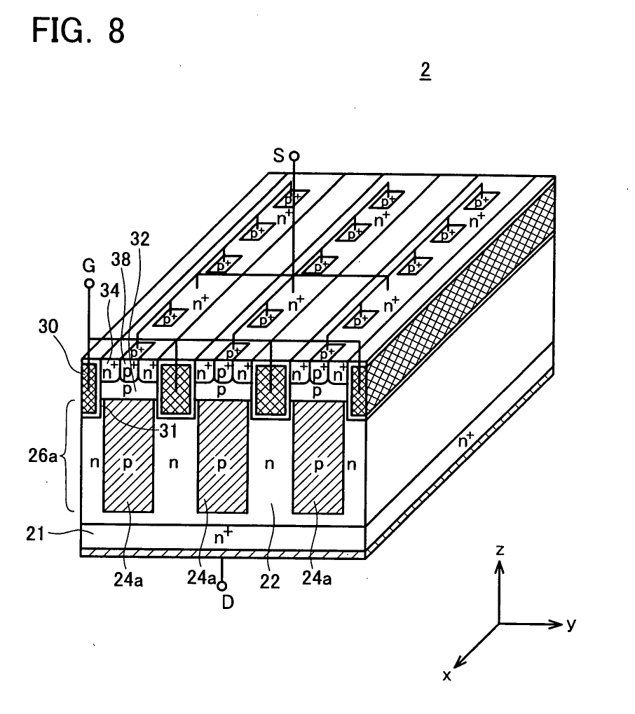

Next, a semiconductor device 2 of a second embodiment will be described with reference to the schematic configuration shown in FIG. 8. As shown in FIG. 8, in the semiconductor device 2, the entirety of p-type semiconductor regions 24a of a super junction structure 26a is formed from Si_{1-x-y}GeₓC_{y} crystal (0≦x<1, 0<y<1, 0<1-x-y<1). The remaining configuration thereof is the same as that of the semiconductor device 1 shown in FIG. 1, and the same reference numbers are applied to the same configurational elements.

After trenches 23 have been formed in the semiconductor device 2 in the same manner as those of the semiconductor device 1 shown in FIG. 3, the p-type semiconductor regions 24a are formed by the crystal growth of p-type Si_{0.91}Ge_{0.08}C_{0.01} film so as to entirely cover the trenches 23. The super junction structure 26a comprising a plurality of n-type semiconductor regions 22 and p-type semiconductor regions 24a is thus formed. The remaining manufacturing processes are the same as in the semiconductor device 1 of the first embodiment, and consequently a description thereof is omitted.

In the semiconductor 2 of the present embodiment, the p-type semiconductor regions 24a are formed only of Si_{0.91}Ge_{0.08}C_{0.01} crystal. As a result, the process of forming the p-type semiconductor regions 24a can be simplified.

### Third Embodiment

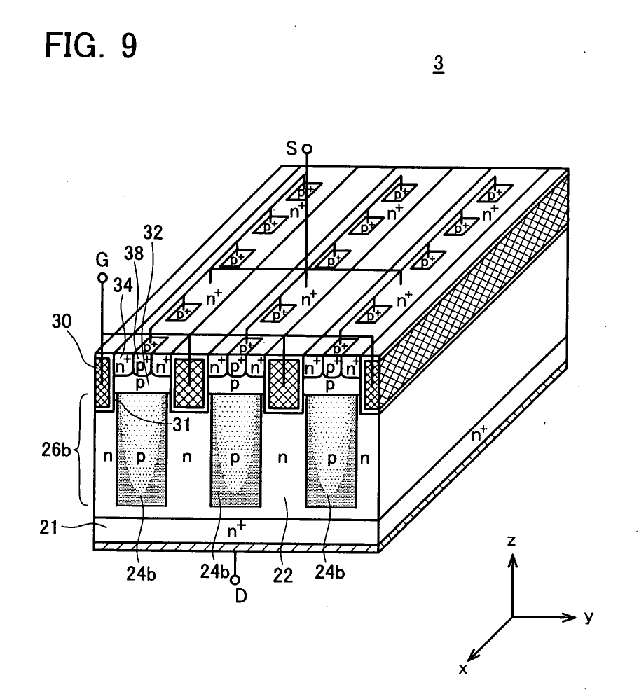

Next, a semiconductor device 3 of a third embodiment will be described with reference to the schematic configuration shown in FIG. 9. As shown in FIG. 9, p-type semiconductor regions 24b of a super junction structure are formed such that the elemental ratio of carbon (C) in the p-type SiGeC film is greater at the junction adjoining the n-type semiconductor regions that form the n-type semiconductor regions 22, and such that the elemental ratio of silicon (Si) increases as a central part of the p-type film is approached. The remaining configuration thereof is the same as that of the semiconductor device 1 shown in FIG. 1, and the same reference numbers are applied to the same configurational elements.

After trenches 23 have been formed in the semiconductor device 3 in the same manner as those of the semiconductor device 1 shown in FIG. 3, the p-type SiGeC films are formed by crystal growth on the trenches 23. In the case where the SiGeC films are grown by CVD (Chemical Vapor Deposition), the elemental ratio of the elements in gas containing the raw materials Si, Ge, and C is set such that the elemental ratio of carbon (C) decreases and the elemental ratio of silicon (Si) increases as the crystal growth progresses. The crystal growth is performed until the p-type semiconductor regions 24b are covered, thus forming a super junction structure 26b comprising a plurality of n-type semiconductor regions 22 and p-type semiconductor regions 24b. The remaining manufacturing processes are the same as in the semiconductor device 1 of the first embodiment, and consequently a description thereof is omitted.

It is preferred that the central part of the p-type semiconductor regions 24b is configured from silicon (Si) single crystal.

During the continuing process of crystal growth, the concentration of Si in the vapor used for the vapor phase deposition may thus be increased as the crystal growth proceeds. The growth rate of crystal is faster for Si crystal than for Si_{1-x-y}GeₓC_{y} crystal (0≦x<1, 0<y<1, 0<1-x-y<1). As a result, it is possible to reduce the time required for filling the trenches 23 with crystal.

### Fourth Embodiment

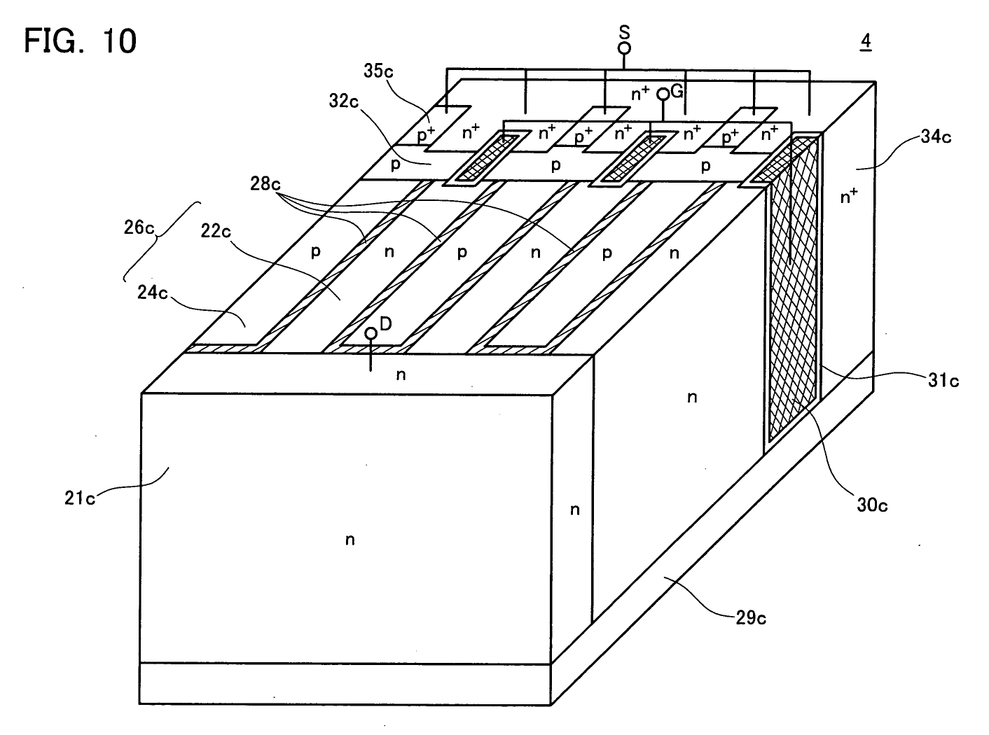

Next, a semiconductor device 4 of a fourth embodiment will be described with reference to the schematic configuration shown in FIG. 10. As shown in FIG. 10, the semiconductor device 4 is configured as a horizontal MOS type FET provided with a super junction structure 26c within a drift region, and an impurity diffusion preventing film 28c that has a thickness of 80 nm and that contains Si_{0.09}Ge_{0.08}C_{0.01} crystal is formed at an edge of a p-type semiconductor region 24c of the super junction structure 26c.

Unlike the vertical MOS type FET semiconductor device 1 shown in FIG. 1, the drain electrode D and the source electrode S are formed on the same plane side (the top surface side in FIG. 10) in the semiconductor device 4. As a result, carriers drift in a horizontal direction with respect to the direction of film thickness of the semiconductor device 4.

The super junction structure 26c is formed by repeating n-type semiconductor regions 22c and the p-type semiconductor regions 24c, each of which extends in the joining direction of the source electrode S and the drain electrode D. The impurity diffusion preventing film 28c is formed at a junction between the n-type semiconductor regions 22c and the p-type semiconductor regions 24c of the super junction structure 26c, and extends across the entire region of the edge of the p-type semiconductor region 24c. The impurity diffusion preventing film 28c (sic) is formed using Si_{0.91}Ge_{0.08}C_{0.01}.

In the Si_{0.91}Ge_{0.08}C_{0.01} crystal contained in the impurity diffusion preventing film 28c, the elemental ratio of carbon (C) is greater than or equal to 0.005, and the diffusion length of impurity is approximately three orders of magnitude smaller than that of impurity inSi crystal. As a result, if this type of crystal is formed between the p-type semiconductor regions 24c and the n-type semiconductor regions 22c that form the super junction structure 26c, it is possible to prevent the mutual diffusion of the p-type impurity and the n-type impurity contained in the Si crystals between the p-type semiconductor regions 24c and the n-type semiconductor regions 22c.

Additionally, when the p-type semiconductor regions 24c that adjoin the Si_{0.91}Ge_{0.08}C_{0.01} crystal are to be formed, the Si crystal of the p-type semiconductor regions 24 (sic) can be grown from the Si_{0.91}Ge_{0.08}C_{0.01} crystal. Furthermore, since the Si crystal and the Si_{0.09}Ge_{0.08}C_{0.01} crystal satisfy the relationship wherein the numerical values of ‘x’ and ‘y’ in S_{1-x-y}GeₓC_{y} are generally x=8.22y and 0≦y≦0.108, misfit dislocation does not readily occur. The manufacturing process of the semiconductor device 4 can thus be simplified.

### Fifth Embodiment

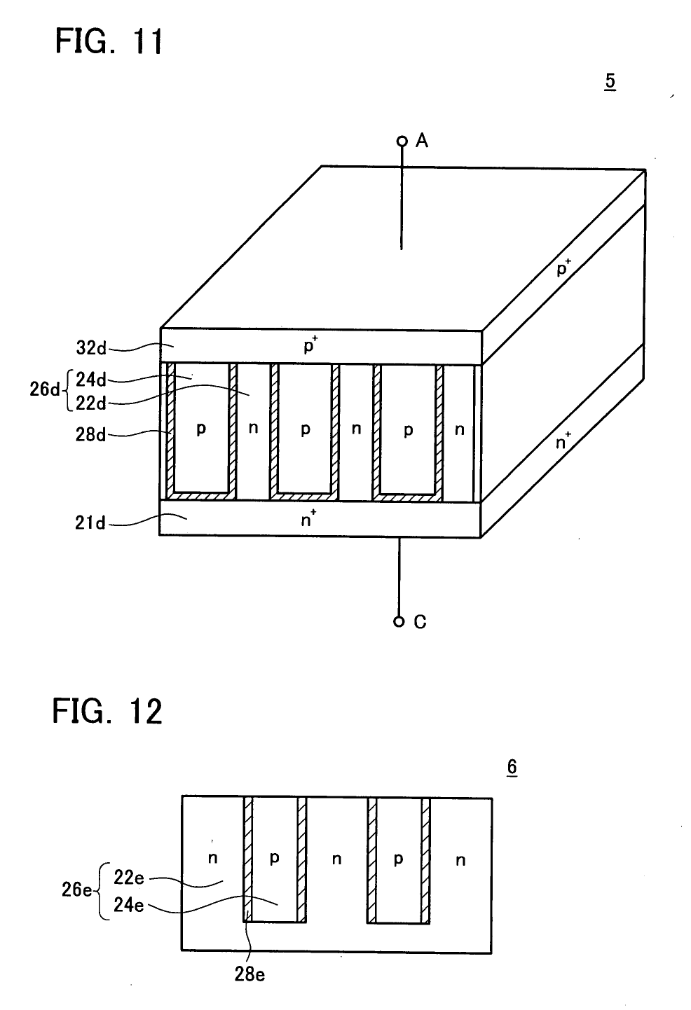

Next, a semiconductor device 5 of a fifth embodiment will be described with reference to the schematic configuration shown in FIG. 11.

As shown in FIG. 11, the semiconductor device 5 is configured as a diode provided with a super junction structure 26d within a semiconductor region between a cathode electrode C and an anode electrode A, and a Si_{0.91}Ge_{0.08}C_{0.01} crystal impurity diffusion preventing film 28d is formed at an edge of a p-type semiconductor region 24d of the super junction structure.

The super junction structure 26d is formed on an n⁺ type semiconductor region 21d that makes contact with the cathode electrode C, and a p⁺ type semiconductor region 32d is formed on the super junction structure 26d, this semiconductor region 32d making contact with the anode electrode A.

The combination of alternating films of n-type semiconductor regions 22d and p-type semiconductor regions 24d in the super junction structure 26d is repeated within a plane orthogonal to the direction joining the cathode electrode C and the anode electrode A.

In the Si_{0.91}Ge_{0.08}C_{0.01} crystal contained in the impurity diffusion preventing film 28d, the elemental ratio of carbon (C) is greater than or equal to 0.005, and the diffusion length of impurity is approximately three orders of magnitude smaller than that of impurity in Si crystal. As a result, if this type of crystal is formed between the p-type semiconductor regions 24d and the n-type semiconductor regions 22d in the repeating direction of the super junction structure 26d, it is possible to prevent the mutual diffusion of the p-type impurity and the n-type impurity contained in the Si crystals between the p-type semiconductor regions 24d and the n-type semiconductor regions 22d.

In addition, when the p-type semiconductor regions 24d adjoining the Si_{0.91}Ge_{0.08}C_{0.01} crystal are to be formed, the Si crystal of the p-type semiconductor regions 24d can be grown from the Si_{0.09}Ge_{0.08}C_{0.01} crystal. Furthermore, since the Si crystal and the S_{0.91}Ge_{0.08}C_{0.01} crystal satisfy the relationship wherein the numerical values of ‘x’ and ‘y’ in Si_{1-x-y}GeₓC_{y} are generally x=8.22y and 0≦y≦0.108, misfit dislocation does not readily occur. The manufacturing process of the semiconductor device 5 can thus be simplified.

In the semiconductor device 1 of the present embodiment, the alloy film consisting of SiGeC that formed the impurity diffusion preventing film 28 was formed across the entire region of the junction of the p-type semiconductor regions 24 with n-type semiconductor regions 22. However, the impurity diffusion preventing film 28 may be formed on a portion of a junction of p-type semiconductor regions 24e with n-type semiconductor regions 22e, as in the semiconductor device 6 shown in FIG. 12.

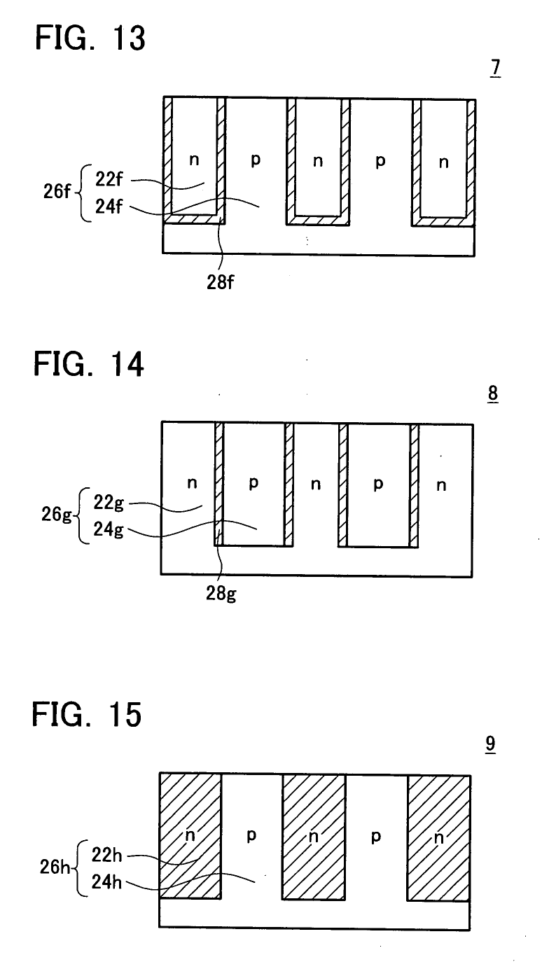

Furthermore, the impurity diffusion preventing film 28 was formed at the p-type semiconductor region 24 side in the semiconductor device 1. However, the impurity diffusion preventing film 28 may equally well be formed at the n-type semiconductor region side, as shown in FIGS. 13 to 15. In a semiconductor device 7 shown in FIG. 13, an impurity diffusion preventing film 28f is formed across the entire region of an inner wall of an n-type semiconductor region 22f at a junction thereof with a p-type semiconductor region 24f. This impurity diffusion preventing film 28f is formed from Si_{0.91}Ge_{0.08}C_{0.01}. The impurity diffusion preventing film 28f may be n-type, p-type, or i type. Additionally, the impurity diffusion preventing film 28 may be formed at a part of a junction of n-type semiconductor regions 22g with p-type semiconductor regions 24g, as in a semiconductor device 8 shown in FIG. 14. Furthermore, the entirety of the n-type semiconductor regions 22h may be formed from Si_{0.91}Ge_{0.08}C_{0.01}, as in a semiconductor device 9 shown in FIG. 15.

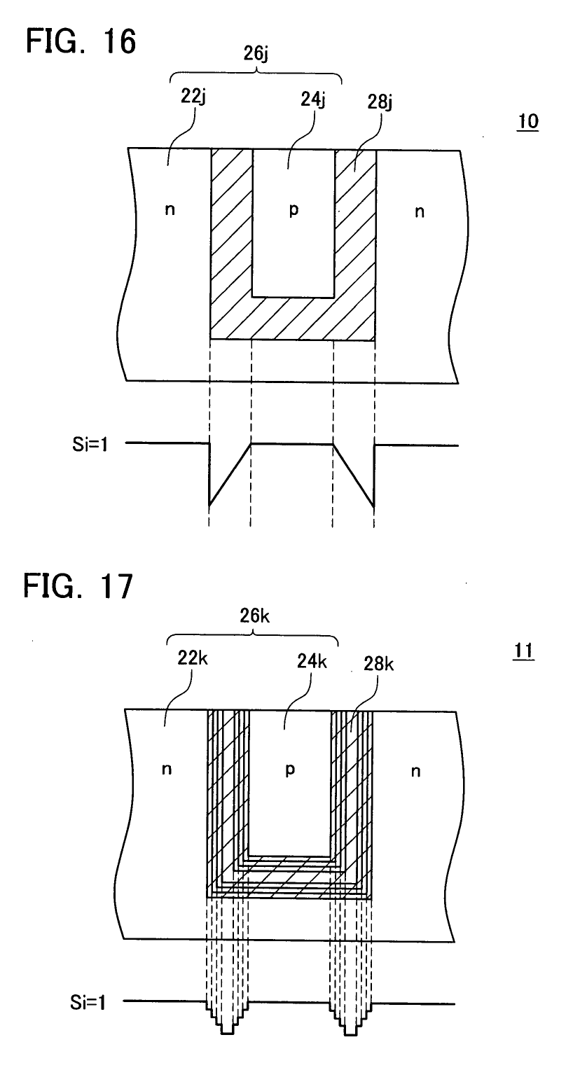

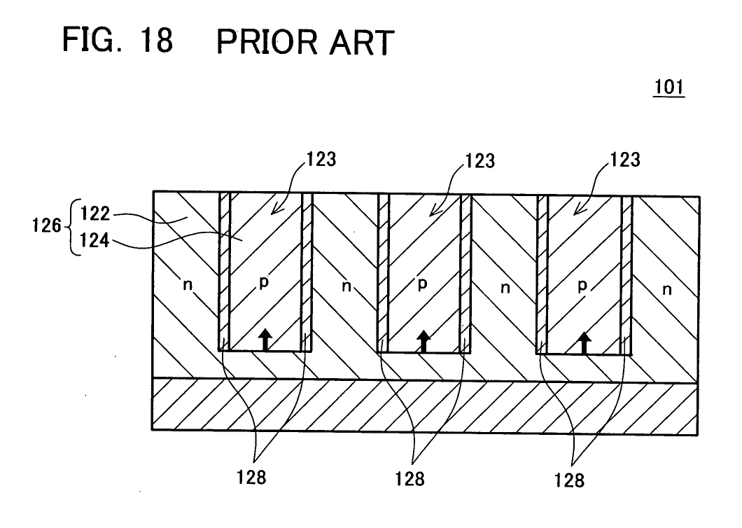

Furthermore, in a semiconductor device 10 shown in FIG. 16, the elemental ratio of Si in Si_{1-x-y}GeₓC_{y} crystal (0≦x<1, 0<y<1, 0<1-x-y<1) that forms an impurity diffusion preventing film 28j increases continually toward Si crystal that forms p-type semiconductor regions 24j. That is, the numerical values of ‘x’ and ‘y’ decrease from the n-type semiconductor region 22j side toward the p-type semiconductor region 24j side. Moreover, the numerical values of ‘x’ and ‘y’ for the Si_{1-x-y}GeₓC_{y} at the junction of the n-type semiconductor region 28j (sic) with the impurity diffusion preventing film 28j are set to be values that satisfy the relationship wherein generally x=8.22y and 0≦y≦0.108. The junction of the impurity diffusion preventing film 28j with the n-type semiconductor region 22j thus forms a perfect lattice match.

With this configuration, the elemental ratio of the Si can be increased the closer the film is to the surface adjoining the p-type semiconductor regions 24j, and lattice mismatch at the junction with the p-type semiconductor regions 24j can be controlled. Simultaneously the elemental ratio of the C can be increased the closer the film is to the surface adjoining the n-type semiconductor regions 22j and, due to the film containing the C, it is possible to effectively prevent the mutual diffusion of impurities between the n-type semiconductor regions 22j and the p-type semiconductor regions 24j. Furthermore, the numerical values of ‘x’ and ‘y’ can be adjusted to prevent lattice mismatch at the junction adjoining the n-type semiconductor regions 22j.

In addition, in a semiconductor device 11 shown in FIG. 17, the elemental ratio of Si in Si_{1-x-y}GeₓC_{y} crystal (0≦x<1, 0<y<1, 0<1-x-y<1) forming an impurity diffusion preventing film 28k increases in steps toward the Si crystal that forms n-type semiconductor regions 22k and toward the Si crystal that forms p-type semiconductor regions 24k. That is, an impurity diffusion preventing film 28k is formed from a plurality of films wherein the numerical values of ‘x’ and ‘y’ differ.

With this configuration, the elemental ratio of carbon (C) can be increased as the central part of the impurity diffusion preventing film 28k is approached. Furthermore, the elemental ratio of silicon (Si) can be increased as the edge parts adjoining the Si crystal are approached. As a result, lattice mismatch does not readily occur at the surface where the impurity diffusion preventing film 28k and the Si crystal join, and the mutual diffusion of impurities between the n-type semiconductor regions and the p-type semiconductor regions can be effectively prevented by the region containing C.

Furthermore, in the first to fourth embodiments, a description has been given where the present invention has been applied to a MOS type FET. However, the present invention can be applied equally well to an IGBT.

Specific examples of the present invention are described above in detail, but these examples are merely illustrative and place no limitation on the scope of the patent claims. The technology described in the patent claims also encompasses various changes and modifications to the specific examples described above.

Furthermore, the technical elements explained in the present specification and drawings provide technical value and utility either independently or through various combinations. The present invention is not limited to the combinations described at the time the claims are filed. Further, the purpose of the example illustrated by the present specification and drawings is to satisfy multiple objectives simultaneously, and satisfying any one of those objectives gives technical value and utility to the present invention.

What is claimed:

1. A semiconductor device comprising:
a super junction structure in which a pair of semiconductor regions, comprising a p-type semiconductor region and an n-type semiconductor region, is disposed repeatedly along at least one direction,
wherein a Si_{1-x-y}GeₓC_{y} (0≦x<1, 0<y<1, 0<1-x-y<1) crystal region is disposed repeatedly along, at least, the aforementioned direction, and
a Si crystal region forming either the p-type semiconductor region or the n-type semiconductor region is disposed between a pair of the Si_{1-x-y}GeₓC_{y} crystal regions.

2. The semiconductor device according to claim 1,
wherein the Si_{1-x-y}GeₓC_{y} crystal region is disposed between the p-type Si crystal region forming the p-type semiconductor region and the n-type Si crystal region forming the n-type semiconductor region.

3. The semiconductor device according to claim 2,
wherein the numerical value of ‘y’ for the Si_{1-x-y}GeₓC_{y} crystal region varies along the aforementioned direction.

4. The semiconductor device according to claim 3,
wherein the numerical value of ‘x’ and the numerical value of ‘y’ for the Si_{1-x-y}GeₓC_{y} crystal region decreases from one side of the Si_{1-x-y}GeₓC_{y} crystal region toward the other side thereof, the one side of the Si_{1-x-y}GeₓC_{y} crystal region facing one Si crystal region at one side, and the other side of the Si_{xy}GeₓC_{y} crystal region facing another Si crystal region at the other side.

5. The semiconductor device according to claim 1,
wherein one of the p-type semiconductor region and the n-type semiconductor region is made of the Si crystal, and the other is made of the Si_{1-x-y}GeₓC_{y} crystal.

6. The semiconductor device according to any one of claims 1 to 5,
wherein the numerical value of ‘y’ is greater than or equal to 0.5×10⁻².

7. A method of manufacturing a semiconductor device including a super junction structure in which a pair of semiconductor regions, comprising a p-type semiconductor region and an n-type semiconductor region, is disposed repeatedly along at least one direction, the method comprising:
forming a plurality of trenches, each of the trenches extending from a top surface of a semiconductor substrate made of Si crystal towards a bottom surface of the semiconductor substrate, and being disposed repeatedly with a predetermined distance between adjacent trenches, and
forming Si_{1-x-y}GeₓC_{y} crystal (0≦x<1, 0<y<1, 0<1-x-y<1) within the trenches.

8. The method of manufacturing the semiconductor device according to claim 7, further comprising:
growing Si crystal on a surface of the Si_{1-x-y}GeₓC_{y} crystal coating an inner surface of the trenches.

9. The method of manufacturing the semiconductor device according to claim 8,
wherein the step of growing the Si_{1-x-y}GeₓC_{y} crystal is controlled so that the numerical value of ‘y’ for Si_{1-x-y}GeₓC_{y} crystal varies along at least the aforementioned direction.

10. The method of manufacturing the semiconductor device according to claim 9,
wherein the step of growing the Si_{1-x-y}GeₓC_{y} crystal is controlled so that an elemental ratio of Si (1-x-y) gradually increases in accordance with the growth of the Si_{1-x-y}GeₓC_{y} crystal, and
the step of growing the Si crystal is continued even after the elemental ratio of Si reaches ‘1.0’ at least until the trenches are filled.

11. The method of manufacturing the semiconductor device according to claim 7, wherein the step of growing the Si_{1-x-y}GeₓC_{y} crystal is continued until the trenches are filled with the Si_{1-x-y}GeₓC_{y} crystal.
